(19) United States
(12) Patent Application Publication
(10) Pub. No.: US 2007/0001704 A1
(43) Pub. Date: Jan. 4, 2007

(54) Method and apparatus for equalization of connection pads

(76) Inventor: Frank O'Mahony, Portland, OR (US)

Correspondence Address: MARSHALL, GERSTEIN & BORUN LLP (INTEL), 233 S. WACKER DRIVE, 6300 SEARS TOWER, CHICAGO, IL, 60606, US

(21) Appl. No.: 11/173,836

(22) Filed: Jun. 30, 2005

(51) Int. Cl. G01R 31/26

(52) U.S. Cl. 324/765

(57) ABSTRACT

An communication system having an on-chip transmitter circuit connected to a channel via an output connection pad and an on-chip receiver circuit connected to the channel via an input connection pad, wherein the on-chip transmitter circuit includes an equalizing output impedance and the on-chip receiver circuit includes an equalizing input impedance. The equalizing output impedance of the on-chip transmitter circuit is adapted to equalize the pad-capacitance of the output connection pad, whereas the equalizing input impedance of the on-chip receiver circuit is adapted to equalize the pad-capacitance of the input connection pad.

### TECHNICAL FIELD

This patent relates generally to integrated circuit chips and more particularly to input output mechanisms of integrated circuit chips.

### BACKGROUND

Electronic systems utilizing integrated circuits have revolutionized the way modern society works and lives by making possible a level of technological sophistication unknown in the days of vacuum tubes and even discrete transistors. These electronic systems are building blocks for ever larger and more complex systems such as machines used in manufacture, transportation and the like. The sophistication of these electronic systems is the result of the complex functions handled by integrated circuits making up the electronic system. An integrated circuit may comprise, on a small silicon chip, many thousand millions or even a billion or more transistors, including associated diodes, resistors and capacitors, interconnected together to form complex electronic functions. The integrated circuit chip or “die” is packaged in an encapsulating package having leads or “pins” for connecting the integrated circuit functions to the overall electronic system or product incorporating a plurality of integrated circuits.

Semiconductor integrated circuits comprise the majority of electronic circuits in computers and other digital electronic products. Present technology integrated circuits may contain billions of transistors and be configured, for example, as a central processing unit (CPU), arithmetic logic unit (ALU), random access memory (RAM), programmable logic array (PLA), application specific integrated circuit (ASIC), or digital signal processor (DSP). Both sophistication and speed of operation of these integrated circuits has rapidly increased because of improvements in integrated circuit manufacturing technologies resulting in smaller and faster devices.

Semiconductor integrated circuits may be formed on silicon wafer dies by a plurality of layers of different materials. These materials are selected for their conduction, insulation or electron charge characteristics. Transistors may be formed into the silicon die by diffusion means well known to those skilled in the art of fabricating integrated circuit dies.

Layers of insulating oxides may be deposited over selected areas of the integrated circuit die so that conductive layers of polysilicon or metal may be deposited thereon. Various methods of deposition may be utilized such as, for example, chemical vapor deposition (CVD) or other methods well known to those skilled in the art of fabricating integrated circuits. Polysilicon may be used as both a circuit element and a conductor such as, for example, the gate structure in a metal oxide semiconductor field effect transistor (MOSFET). Metal is used for interconnection between various circuit elements and for connection to the integrated circuit connection pads.

Connections from the integrated circuit die are generally made by means of the connection pads. The connection pads are located on the face of the integrated circuit die. Bond wires connect the pads to a lead frame which becomes the pins of the integrated circuit package that connect to the electronic system. Another way in which these connection pads may be connected to the package is through an array of small solder bumps that allow the chip to be placed directly on the package with connections made right at the interface between them.

These connection pads on the face of the integrated circuit die may be about 60 to 100 micrometers on a side and may be substantially square. The connection pad is mostly parallel with the face of the die and the pad may have a thickness of about from 0.7 to 1 micrometer. Generally, there are one or more insulating layers between the metal connection pad and the surface of the silicon wafer die or “substrate” face. There may also be one or more additional layers of metal and/or polysilicon between the substrate and the connection pad.

The connection pad surface and the underlying metal or substrate form a capacitor wherein the pad is the positively charged plate at a logic high level, typically V.sub.dd, the substrate is the negatively charged plate at V.sub.ss, and intervening insulation therebetween is the dielectric. Typically, capacitance associated with a connection pad, generally known as pad capacitance, is about 0.1 to 1 picofarad (pF). The pad capacitance is added to the capacitance of the integrated circuit package and electronic system circuit board. The package and system circuit capacitance may be about 5 pF per connection. Thus, the connection pad adds a significant amount of capacitance to the overall system capacitance per connection.

Any circuit capacitance must be charged when going from a low to high logic state, and discharged when going from a high to low logic state. Charging of the circuit capacitance is performed by an output driver circuit such as, for example, a complementary metal oxide semiconductor (CMOS) transistor amplifier. A CMOS output driver, however, must be designed with electrostatic discharge (ESD) protection in mind. The design rules for CMOS ESD protection restrict the CMOS driver performance, including the current drive capability needed to charge and discharge output circuit capacitance.

Inputs to the integrated circuit die also utilize connection pads similar to the output pads described above. When an input is connected to an output, the input capacitance adds to the overall circuit connection capacitance. Input capacitance may be about 0.1 to 1 pF. This amount of input capacitance is significant and represents the majority of the connected capacitance, especially when multiple integrated circuit dice are connected in a hybrid package utilizing close coupled wire bonding therebetween.

Since CMOS transistor amplifier capacitive drive capabilities are limited because of ESD design constraints, what is needed is a way of reducing the output capacitance charge requirements, and, preferably, the input capacitance charge requirements caused by the connection pad capacitance of the integrated circuit die. By reducing overall connection capacitance charging requirements, smaller driver transistors may be utilized in the output amplifiers of the integrated circuit, which results in a smaller integrated circuit die or the capability of having more transistor functions on a given die size, therefore enabling more complex electronic systems that operate faster and with lower power requirements.

When an integrated circuit is used in a communication system, the pad capacitance affects the impedance and therefore the signal transfer efficiency of the communication system. For example, a receiver integrated circuit with pad capacitance affects the amount of input signal transferred into the receiver while a transmitter integrated circuit with pad capacitance affects the amount of output signal transferred from the transmitter. Subsequently, the pad capacitance results in loss of signal over the communication system. Signal reflections at these impedance discontinuities also cause inter-symbol interference (ISI), which is also detrimental to signal integrity.

To address the above problems, it is desirable to provide an improved receiver integrated circuit that provides optimal input impedance as well as an improved transmitter integrated circuit that provides optimal output impedance. Most conventional high-frequency transceivers attempt to match the impedance of off-chip transmission lines with a resistor. An exemplary conventional current-mode transceiver circuit providing resistive impedance parallel to the pad capacitance of the transceiver circuit 10 is illustrated in FIG. 1. Specifically, the transceiver circuit 10 includes a transmitter circuit 12, a communication channel 14 and a receiver circuit 16, wherein the transmitter circuit 12 includes a resistor 20 connected in parallel to the output pad capacitance 22 and the receiver circuit 16 includes a resistor 24 connected in parallel to the input pad capacitance 26.

For signaling with low- to moderate-bandwidth signals (<1 GHz) and/or for transceivers with low pad capacitances (<<1 pF), this technique is effective because the impedance of the parasitic capacitance is much larger than the impedance of the transmission line over the bandwidth of the signals (R0<<|1/jωC|). In this case, nearly all of the signal power passes from the on-chip transmitter to the off-chip transmission line or from the off-chip transmission line to the on-chip receiver and almost none is reflected at the interface. However, for high-bandwidth signals (>1 GHz) with large parasitic pad capacitance (˜1 pF), the impedance of the capacitance can easily be comparable to or less than the impedance of the matching resistor for the high-frequency components of the signal. In this case, a significant amount of the signal power is reflected at the interface between the on-chip circuitry and off-chip transmission line, effectively increasing the overall channel loss and contributing to the ISI. This in turn will either reduce the achievable data rate or increase the required power or complexity of the transceiver Some signaling systems compensate for this high-frequency loss with some form of “equalization” within the first stage of the input amplifier or with pre-emphasis in the transmitter. However, incorporating equalization within these circuit blocks does nothing to reduce channel loss or ISI, it only compensates for it at a later stage in the circuit. Therefore, it is necessary to provide a better solution to mitigate the detrimental effects of parasitic pad capacitance for high frequency chip-to-chip signaling.

### BRIEF DESCRIPTION OF THE DRAWINGS

The present patent is illustrated by way of examples and not limitations in the accompanying figures, in which like references indicate similar elements, and in which:

FIG. 1 illustrates a block diagram of an exemplary prior art transceiver circuit;

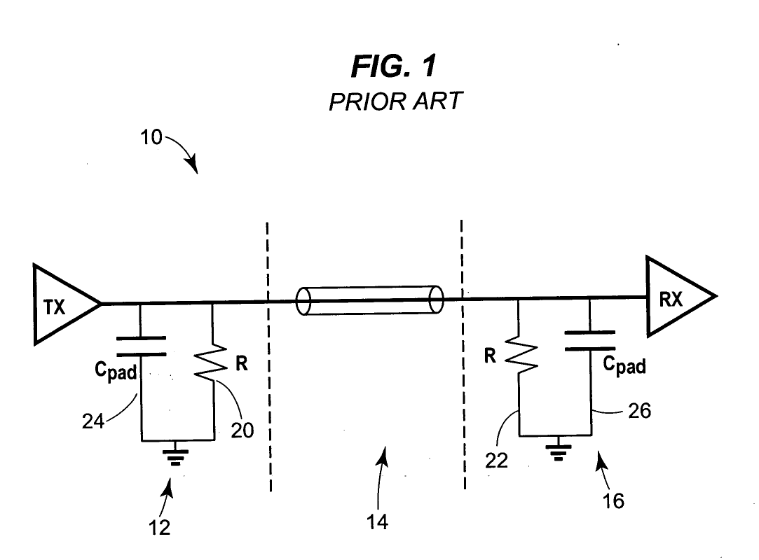

FIG. 2 illustrates a block diagram of an exemplary transmitter circuit having equalizing output impedance;

FIG. 3 illustrates a block diagram of an exemplary transmitter circuit having variable equalizing output impedance;

FIG. 4 illustrates a block diagram of an exemplary receiver circuit having equalizing input impedance;

FIG. 5 illustrates a block diagram of an exemplary receiver circuit having variable equalizing input impedance;

FIG. 6 illustrates a block diagram of an exemplary transceiver circuit having equalizing input impedance and an equalizing output impendence;

FIG. 7 illustrates a block diagram of an exemplary differential transceiver circuit having an equalizing input impedance and an equalizing output impendence; and

FIG. 8 illustrates frequency responses of a receiver circuit having equalizing input impedance.

### DETAILED DESCRIPTION OF THE EXAMPLES

In the following detailed description of numerous different embodiments, reference is made to the accompanying drawings which form a part hereof, and in which is shown, by way of illustration, specific embodiments by which the present patent may be implemented. In the drawings, like numerals describe substantially similar components throughout the several views. These embodiments are described in sufficient detail to enable those skilled in the art to practice the present patent. Other embodiments may be utilized and structural, logical and electrical changes may be made without departing from the scope of the present patent. The following detailed description is therefore, not to be taken in a limiting sense and the scope of the present patent is defined only by the appended claims, along with the full scope of equivalents to which such claims are entitled.

An embodiment of the present patent provides a communication system having an on-chip transmitter circuit connected to a channel via an output connection pad and an on-chip receiver circuit connected to the channel via an input connection pad, wherein the on-chip transmitter circuit includes equalizing output impedance and the on-chip receiver circuit includes equalizing input impedance. The equalizing output impedance of the on-chip transmitter circuit may be adapted to equalize the pad capacitance of the output connection pad, whereas the equalizing input impedance of the on-chip receiver circuit may be adapted to equalize the pad-capacitance of the input connection pad. In such an embodiment, the inductors providing the equalizing impedances may be selected in a manner so as to resonate with the pad capacitances to cancel out the effect of the pad capacitances.

In an alternate embodiment, the inductors providing the equalizing impedances may be selected in a manner so that the equalizing impedances compensate for channel loss of the communication system by, for example, over-equalizing for the pad capacitances. In yet another embodiment, the inductors providing the equalizing impedances may be selected in a manner so as to achieve maximum data rate or a minimal bit error rates (BER) for the communication system. The transmitter and the receiver of the communication system may communicate with the channel using baseband techniques such as binary signaling method, also known as 2-level pulse amplitude modulation (2-PAM) signaling method, 4-PAM signaling method, or any other communication methods.

An alternate embodiment of the present patent provides a transmitter circuit connected to an output channel via an output connection pad wherein the output impedance of the transmitter circuit is matched to the input impedance of the output channel using an equalization circuit connected in parallel to the pad capacitance of the transmitter. In an alternate embodiment of such a transmitter circuit, the inductor used for matching the output impedance of the transmitter circuit to the input impedance of the output channel is a variable inductor that is controlled by a control circuit or by software. In an alternate embodiment of such a transmitter circuit the inductor may be selected in a manner so that the equalizing impedances compensate for channel loss of the transmitter circuit by, for example, over-equalizing for the pad capacitance. In yet another embodiment, the inductors providing the equalizing impedances may be selected in a manner so as to achieve maximum data rate or a minimal BER for the transmitter.

An alternate embodiment of the present patent provides a receiver circuit connected to an input channel via an input connection pad wherein the input impedance of the receiver circuit matched to the output impedance of the input channel using an equalization circuit connected in parallel to the pad capacitance of the receiver circuit. In an alternate embodiment of such a receiver circuit, the inductor used for matching the input impedance of the receiver circuit with the output impedance of the input channel is a variable inductor that is controlled by a control circuit or by software.

In an alternate embodiment of such a receiver circuit the inductor may be selected in a manner so that the equalizing impedances compensate for channel loss of the receiver by, for example, over-equalizing for the pad capacitance. In yet another embodiment, the inductors providing the equalizing impedances may be selected in a manner so as to achieve maximum data rate or a minimal BER for the receiver. In yet another embodiment, the inductors providing the equalizing impedances may be selected in a manner so as to achieve maximum power transfer for the receiver.

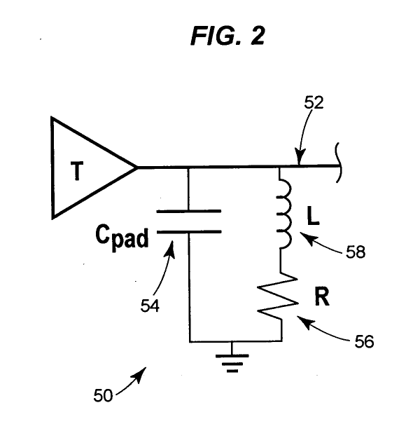

Now referring to the accompanying figures, FIG. 2 illustrates an on-chip transmitter circuit 50 connected to an output channel 52 via an output connector pad having an output pad-capacitance 54. The transmitter circuit 50 further includes an impedance matching circuit that includes a resistor 56 and an inductor 58. A signal output by the transmitter circuit 50 is transferred to the output channel 52 based on a transfer function that is dependent on the impedance matching between the transmitter circuit 50 and the output channel 52. It is well known to one of ordinary skill in the art that such a transfer function is dependent on the operating frequency of the transmitter circuit 50.

The transmitter circuit 50 may be designed in a manner so that when the transmitter circuit 50 is operating at higher frequencies, say above 1 GHz, the input impedance of the channel 52 matches the output impedance of the transmitter circuit 50 determined by the parallel pad capacitance C_{pad} 54, inductance of the inductor 58 and the resistance of the resistor 56. For this approach, matching the impedances constitutes selecting values for the passive components in a manner so that the overall impedance looking into the transmitter pad is identical or close to the complex conjugate of channel impedance over a range of frequencies. Such matching of the output impedance of the transmitter circuit 50 with the input impedance of the channel 52 results in lower amount of signal reflection and subsequently in higher amount of signal transferred from the transmitter circuit 50 to the channel 52.

Alternatively, the transmitter circuit 50 may be designed in a manner so that the inductance of the inductor 58 may compensate for any loss of signal experienced by the channel 52. Alternatively, the transmitter circuit 50 may be designed by selecting the inductor 58 in a manner so that the inductance of the inductor 58 maximizes the data rate of the channel 52 and/or minimizes the BER of the channel 52. Alternatively, the transmitter circuit 50 may be designed by selecting the inductor 58 in a manner so that the inductance of the inductor 58 maximizes the power transfer of the channel 52.

The transmitter circuit 50 described in here may be used for a variety of signaling and communication methods. For example, an implementation of the transmitter circuit 50 may be used for multi-level signaling such as 2-PAM signaling method, 4-PAM signaling method, etc. Similarly, while the signaling method used by the transmitter circuit 50 is single ended, in an alternate implementation of transmitter circuit 50 may also use a differential signaling method.

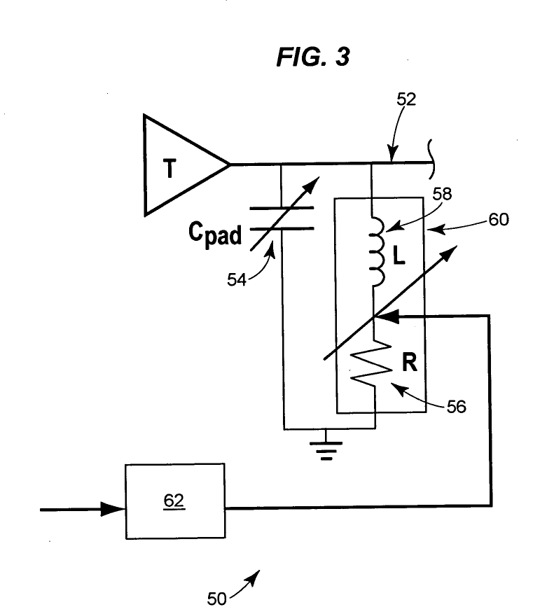

While the inductor 58 used in FIG. 2 is shown to be a passive inductor, in practice the inductor 58 may also be an active inductor or a variable inductor. FIG. 3 illustrates an implementation of the transmitter circuit 50 using variable impedance 60, which includes the resistor 56 and the inductor 58. In an alternative implementation of the transmitter circuit 50, the equalizing impedance 60 may also include a variable capacitor (not shown here). The variable impedance 60 may be controlled by a control circuit 62, wherein the control circuit 62 may receive an input signal form the transmitter circuit 50, from a receive end of the channel 52, etc., and provide a control signal to the variable impedance 60.

Thus, for example, the control system 62 may receive an input signal indicating the data transfer rate of the channel 52 and based on the data transfer rate of the channel 52 the control system 62 may adjust the total impedance of the variable impedance 60 in a manner so that the data transfer rate of the channel 52 is optimal. Alternatively, the control system 62 may receive an input signal indicating the BER, voltage margin and/or timing margin of the channel 52 and based on this information the control system 62 may adjust the total impedance of the variable impedance 60 in a manner so that the BER of the channel 52 is minimal.

The control system 62 may adjust the total impedance of the variable impedance 60, for example, by varying the amount of resistance provided by the resistor 56, by varying the amount of inductance provided by the inductor 58, by varying the amount of effective capacitance in parallel to the equalizing impedance 60 provided by the resistor 56 and the inductor 58, or any other desired manner. The control system 62 may be designed using hardware, firmware, software or any combination thereof.

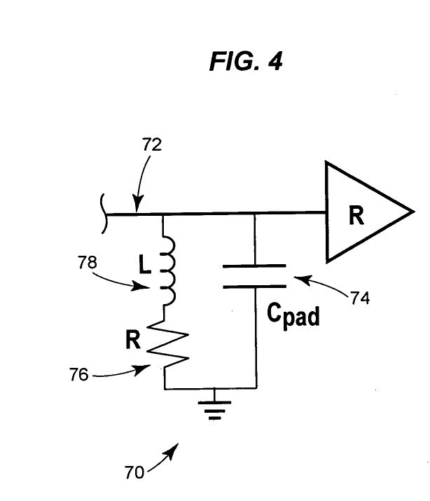

FIG. 4 illustrates an on-chip receiver circuit 70 connected to an input channel 72 via an input connector pad having an input pad-capacitance 74. The receiver circuit 70 further includes an impedance matching circuit that includes a resistor 76 and an inductor 78. A signal input to the receiver circuit 70 is transferred from the input channel 72 based on a transfer function that is dependent on the impedance matching between the receiver circuit 70 and the input channel 72. It is well known to one of ordinary skill in the art that such a transfer function is dependent on the operating frequency of the receiver circuit 70.

The receiver circuit 70 may be designed in a manner so that when the receiver circuit 70 is operating at higher frequencies, say above 1 GHz, the output impedance of the channel 72 matches the input impedance of the receiver circuit 70 determined by the pad capacitance C_{pad} 74, inductance of the inductor 78 and the resistance of the resistor 76. For this approach, matching the impedances constitutes selecting values for the passive components in a manner so that the overall impedance looking into the receiver pad is identical or close to the complex conjugate of channel impedance over a range of frequencies. Such matching of the input impedance of the transmitter circuit 70 with the output impedance of the channel 72 results in lower amount of signal reflection and subsequently in higher amount of signal transferred from the channel 72 to the receiver circuit 70.

Alternatively, the receiver circuit 70 may be designed in a manner so that the inductance of the inductor 78 compensates for any loss of signal experienced by the channel 72. Alternatively, the receiver circuit 70 may be designed by selecting the inductor 78 in a manner so that the inductance of the inductor 78 maximizes the data rate of the channel 72 and/or minimizes the BER of the channel 72. Alternatively yet, the receiver circuit 50 may be designed by selecting the inductor 78 in a manner so that the inductance of the inductor 78 maximizes the power transfer of the channel 72.

The receiver circuit 70 described in here may be used for a variety of signaling and communication methods. For example, an implementation of the receiver circuit 70 may be used for multi-level signaling such as 2-level pulse amplitude modulation (2-PAM) signaling method, 4-PAM signaling method, etc. Similarly, while the signaling method used by the receiver circuit 70 is single ended, in an alternate implementation of receiver circuit 70 may also use a differential signaling method.

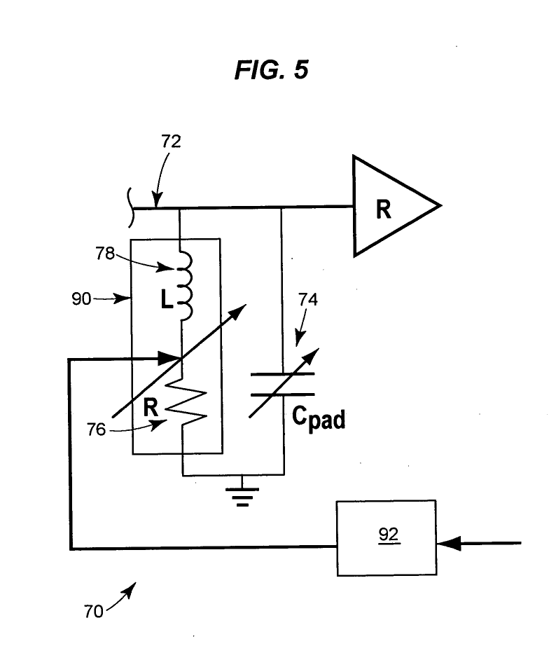

While the inductor 78 used in FIG. 4 is shown to be a passive inductor, in practice the inductor 78 may also be an active inductor or a variable inductor. FIG. 5 illustrates an implementation of the receiver circuit 70 using variable impedance 90, which includes the resistor 76 and the inductor 78. In an alternative implementation of the receiver circuit 70, the equalizing impedance 90 may also include a variable capacitor (not shown here). The variable impedance 90 may be controlled by a control circuit 92, wherein the control circuit 92 may receive an input signal form the receiver circuit 70, from the channel 72, etc., and provide a control signal to the variable impedance 90.

Thus, for example, the control system 92 may receive an input signal indicating the data transfer rate of the channel 72 and based on the data transfer rate of the channel 72 the control system 92 may adjust the total impedance of the variable impedance 80 in a manner so that the data transfer rate of the channel 72 is optimal. Alternatively, the control system 92 may receive an input signal indicating the BER, voltage margin, and/or timing margin of the channel 72 and based on this information, the control system 92 may adjust the total impedance of the variable impedance 80 in a manner so that the BER of the channel 72 is minimal.

The control system 92 may adjust the total impedance of the variable impedance 80, for example, by varying the amount of resistance provided by the resistor 76, by varying the amount of effective capacitance in parallel to the equalizing impedance 90 provided by the resistor 76 and the inductor 78, by varying the amount of inductance provided by the inductor 78, or any other desired manner. The control system 92 may be designed using hardware, firmware, software or any combination thereof.

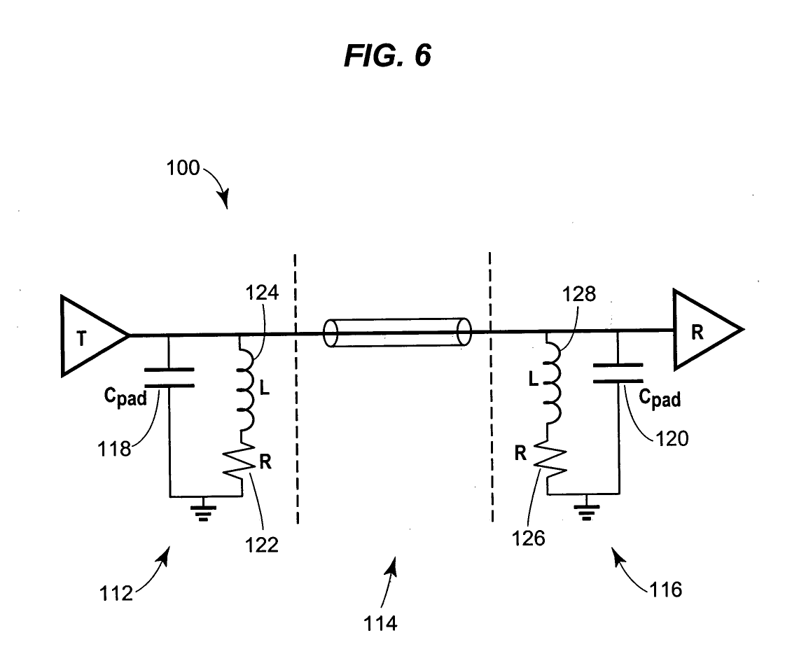

FIG. 6 illustrates a transceiver system 100 including a transmitter circuit 112, a communication channel 114 and a receiver circuit 116. The transmitter circuit 112 is connected to the channel 114 via an output connection pad having a pad capacitance 118, while the receiver circuit 116 is connected to the channel 114 via an input connection pad having a pad capacitance of 120. The transmitter circuit 112 further includes an impedance matching circuit that includes a resistor 122 and an inductor 124. A signal output by the transmitter circuit 112 is transferred to the communication channel 114 based on a transfer function that is dependent on the impedance matching between the transmitter circuit 112 and the communication channel 114. Similarly, the receiver circuit 116 further includes an impedance matching circuit that includes a resistor 126 and an inductor 128. A signal input to the receiver circuit 116 is transferred from the communication channel 114 based on a transfer function that is dependent on the impedance matching between the receiver circuit 116 and the communication channel 114. It is well known to one of ordinary skill in the art that such a transfer function may be dependent on the operating frequency of the transceiver system 100.

The transceiver system 100 may be designed in a manner so that when the transceiver system 100 is operating at higher frequencies, say above 1 GHz, the input impedance of the communication channel 114 matches the output impedance of the transmitter circuit 112 as determined by the pad capacitance C_{pad} 118, inductance of the inductor 124 and the resistance of the resistor 122, while the output impedance of the communication channel 114 matches the input impedance of the receiver circuit 116 as determined by the pad capacitance C_{pad} 120, inductance of the inductor 128 and the resistance of the resistor 126. For this approach, matching the impedances constitutes selecting values for the passive components in a manner so that the overall impedances looking into the receiver pad and looking into the transmitter pad are identical or close to the complex conjugate of channel impedances, at the point of connection of the channel to the respective pads, over a range of frequencies. Such matching of the output impedance of the transmitter circuit 112 with the input impedance of the communication channel 114 and the matching of the input impedance of the receiver circuit 116 with the output impedance of the communication channel 114 results in lower amount of signal reflection and subsequently in higher amount of signal transferred within the transceiver system 100.

Alternatively, the transceiver system 100 may be designed in a manner so that the inductances of the inductors 118 and 128 compensate for any loss of signal experienced by the communication channel 114. Alternatively, the transceiver system 100 may be designed by selecting the inductors 118 and 128 in a manner so that the inductances of the inductors 118 and 128 maximize the data rate of the communication channel 114 and/or minimize the BER of the communication channel 114. Alternatively, the transceiver system 100 may be designed by selecting the inductors 118 and 128 in a manner so that the inductances of the inductors 118 and 128 maximize the power transfer of the communication channel 114.

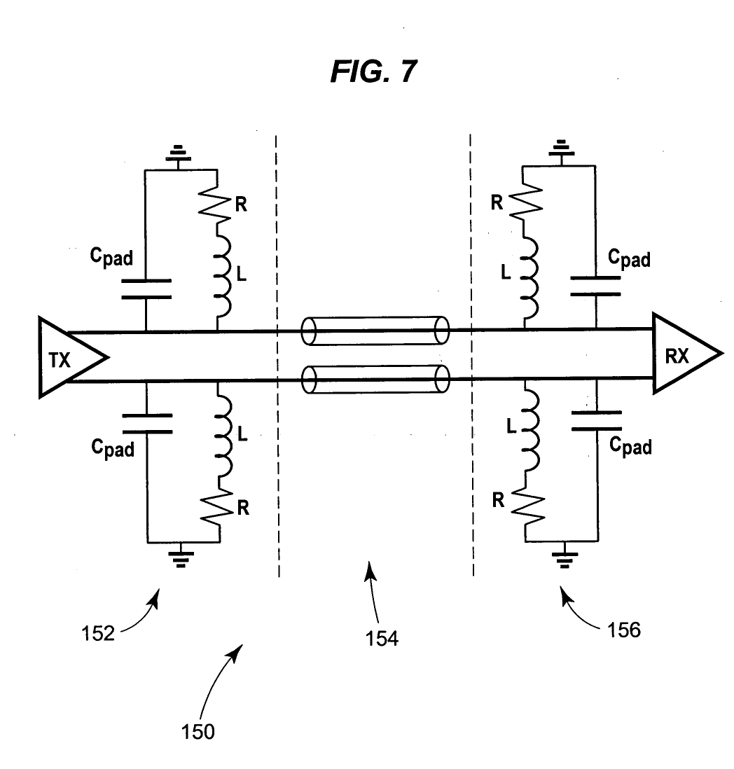

While FIGS. 2-6 illustrate various implementations of communication systems using equalizing impedance at the input/output of a receiver/transmitter using single ended signaling, such an impedance matching can also be applied to a communication system using differential signaling method. FIG. 7 illustrates a block diagram of an exemplary differential transceiver circuit 150 including a transmitter circuit 152, a plurality of communication channels 154 and a receiver circuit 156. As illustrated in FIG. 7, impedance matching may be used at the input/output of each of the plurality of communication channels 154 in a manner so that the power transfer and the data transfer rates of each of the plurality of communication channels 154 is maximized while the BER of each of the plurality of communication channels 154 is minimized.

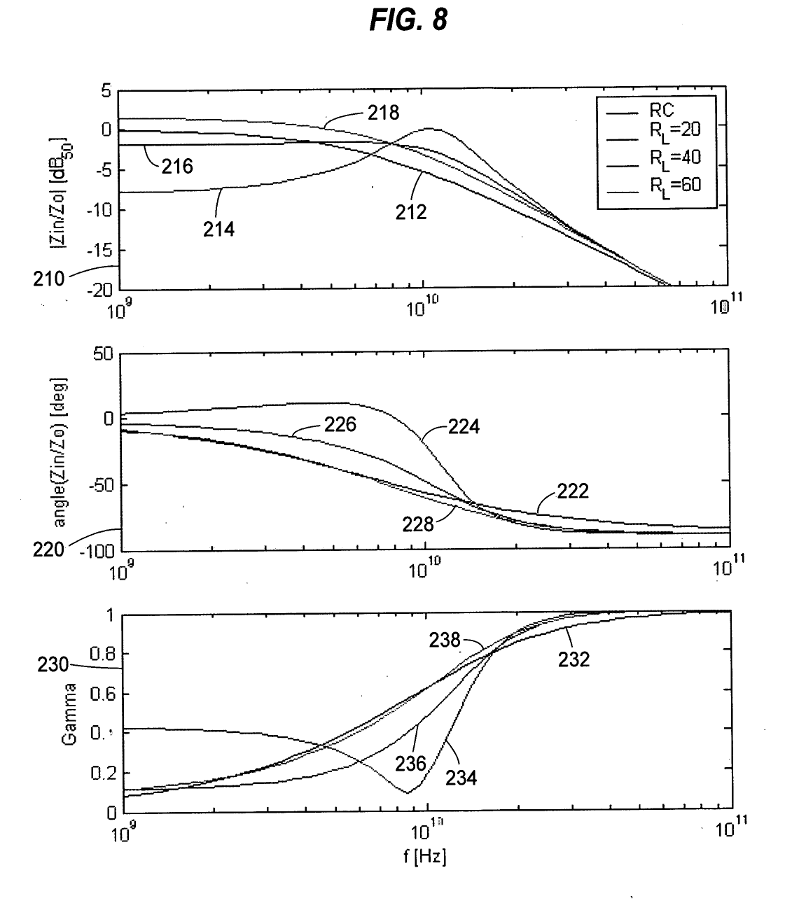

FIG. 8 illustrates frequency responses of a receiver or a transmitter circuit, both with and without, equalizing input/output impedance. Specifically, FIG. 8 illustrates frequency-dependent impedance seen looking into the transmitter or the receiver pad, both with and without, an inductor. For illustration purposes, the resistance looking into the receiver/transmitter is set to be at a reasonable value of 50 ohms and the pad capacitance of the receiver/transmitter is set to be at a reasonable value of 0.5 fF.

The graph 210, 220 and 230 respectively show the magnitude of the impedance, the angle of the impedance, and the reflection coefficient (Gamma) of the impedance looking into the receiver/transmitter pad. Specifically, the graphs 212, 222 and 232, respectively, show the magnitude, the angle and the reflection coefficient of the impedance looking into the receiver/transmitter pad without an inductor at the pad.

As it can be seen from the graphs 212, 222 and 232, the impedance reduces at high frequencies due to the single-pole roll-off of the pad capacitance and termination resistance. Gamma is a good figure of merit for how much of a signal gets reflected when it reaches this termination, with a value of 0 being ideal (no reflection) and a value of 1 being the worst case where the entire signal is reflected. Large reflection coefficients lead to ISI and reduce the signal amplitude when it occurs at the receiver.

On the other hand, the other three graphs show the magnitude, the angle and the reflection coefficient of the impedance looking into the receiver/transmitter pad with an inductor of 25 nH in series with the resistor. Specifically, the graphs 214, 224 and 234, respectively, show the magnitude, the angle and the reflection coefficient of the impedance; looking into the receiver/transmitter pad with a resistor of 20Ω at the pad, the graphs 216, 226 and 236, respectively, show the magnitude, the angle and the reflection coefficient of the impedance looking into the receiver/transmitter pad with a resistor of 40Ω at the pad, and the graphs 218, 228 and 238, respectively, show the magnitude, the angle and the reflection coefficient of the impedance looking into the receiver/transmitter pad with a resistor of 60Ω at the pad.

The inductor may be chosen to resonate with the capacitor at roughly the same frequency where the capacitor starts to cause the impedance to reduce. The three graphs show how an improvement in the reflection co-efficient can be achieved for about a decade of frequency, from several gigahertz to more than ten gigahertz. This improvement in matching would result in a reduction in ISI and improved signal amplitude at the receiver. This example also illustrates how the impedance could be adapted by modifying the termination resistance in series with the inductor.

Although the forgoing text sets forth a detailed description of numerous different embodiments, it should be understood that the scope of the patent is defined by the words of the claims set forth at the end of this patent. The detailed description is to be construed as exemplary only and does not describe every possible embodiment because describing every possible embodiment would be impractical, if not impossible. Numerous alternative embodiments could be implemented, using either current technology or technology developed after the filing date of this patent, which would still fall within the scope of the claims of this patent.

Thus, many modifications and variations may be made in the techniques and structures described and illustrated herein without departing from the spirit and scope of the present patent. Accordingly, it should be understood that the methods and apparatus described herein are illustrative only and are not limiting upon the scope of the patent.

1. A communication system having a transmitter circuit connected to a channel via an output connection pad and a receiver circuit connected to the channel via an input connection pad, comprising:
an equalizing output impedance connected to the output connection pad of the transmitter circuit; and
an equalizing input impedance connected to the input connection pad of the receiver circuit.

2. A communication system of claim 1, wherein the equalizing output impedance is implemented using an output inductor in parallel with an output pad capacitance of the output connection pad.

3. A communication system of claim 2, wherein the equalizing output impedance further includes an output resistor connected in series with the output inductor.

4. A communication system of claim 2, wherein the control circuit is further adapted to receive the input from the transmitter circuit and to adjust the equalizing output impedance of the transmitter circuit based on the input in a manner so as to at least one of: (1) maximize the power transfer of the communication system; (2) maximize the data transfer rate of the communication system; (3) minimize the bit error rate of the communication system; or (4) match the equalizing output impedance of the transmitter to an input impedance of the channel.

5. A communication system of claim 1, wherein the equalizing input impedance is implemented using an input inductor in parallel with an input pad capacitance of the input connection pad.

6. A communication system of claim 5, wherein the equalizing input impedance further includes an input resistor connected in series with the input inductor.

7. A communication system of claim 6, wherein the control circuit is further adapted to receive the control input from the receiver circuit and to adjust the equalizing input impedance of the receiver circuit based on the input in a manner so as to at least one of: (1) maximize the power transfer of the communication system; (2) maximize the data transfer rate of the communication system; (3) minimize the bit error rate of the communication system; or (4) match the equalizing input impedance of the transmitter to an output impedance of the channel.

8. A communication system of claim 1, wherein the receiver circuit and the transmitter circuit are further adapted to communicate over the channel using a broadband signaling technique.

9. A communication system of claim 8, wherein the receiver circuit and the transmitter circuit are further adapted to communicate over the channel using at least one of: (1) 2-level pulse amplitude modulation signaling; or (2) 4-level pulse amplitude modulation signaling.

10. A communication system of claim 1, wherein the channel includes a plurality of communication channels and the receiver circuit and the transmitter circuit are further adapted to communicate with the plurality of communication channels using differential signaling.

11. A transmitter circuit for communicating a signal to an output channel, the transmitter circuit comprising:
a connection pad having a pad capacitance and connecting the signal from the transmitter circuit to the output channel; and
an equalization circuit connected to connection pad and adapted to at least one of (1) match an input impedance of the channel to an output impedance of the transmitter circuit; (2) maximize the power transfer of the transmitter circuit; (3) maximize the data transfer rate of the transmitter circuit; or (4) minimize the bit error rate of the transmitter circuit, wherein the equalization circuit includes an equalizing impedance connected in parallel to the pad capacitance.

12. (canceled)

13. A transmitter circuit of claim 12, wherein the equalizing impedance includes at least one of a variable inductor, a variable capacitor or a variable resistor.

14. A receiver circuit for receiving a signal from an input channel, the receiver circuit comprising:
a connection pad having a pad capacitance and connecting the signal from the channel to the receiver circuit; and
an equalization circuit connected to connection pad and adapted to at least one of: (1) match an output impedance of the channel to an input impedance of the receiver circuit; (2) maximize the power transfer of the receiver circuit; (3) maximize the data transfer rate of the receiver circuit; or (4) minimize the bit error rate of the receiver circuit, wherein the equalization circuit includes an equalizing impedance connected in parallel to the pad capacitance.

15. (canceled)

16. A receiver circuit of claim 15, wherein the equalizing impedance includes at least one of a variable inductor, a variable capacitor or a variable resistor.

17. A method of communicating a signal from a transmitter to a receiver via a communication channel, wherein the transmitter is connected to the communication channel via an output pad and the receiver is connected to the communication channel via an input pad, the method comprising:
communicating the signal from the transmitter to the communication channel;
determining an first feedback signal based on at least one of: (1) data transfer ratio between the transmitter to the communication channel, (2) power transfer rate between the transmitter to the communication channel, (3) bit error rate of the communication channel, or (4) impedance match between the transmitter and the communication channel;
adjusting an input equalizing impedance of the communication channel based on the first feedback signal;
receiving the signal from the communication channel at the receiver;
determining a second feedback signal based on at least one of: (1) data transfer ratio between the communication channel and the receiver, (2) power transfer rate between the communication channel and the receiver, (3) bit error rate of the communication channel, or (4) impedance match between the communication channel and the receiver; and
adjusting an output equalizing impedance of the communication channel based on the second feedback signal.

18. A method of claim 17, wherein the transmitter and the receiver are further adapted to communicate with the communication channel using a broadband signaling technique.

19. A method of claim 18, wherein the transmitter and the receiver are further adapted to communicate with the communication channel using at least one of: (1) 2-level pulse amplitude modulation signaling; or (2) 4-level pulse amplitude modulation signaling.

20. A method of claim 17, wherein the transmitter and the receiver are further adapted to communicate with the communication channel using at least one of: (1) single ended signaling or (2) differential signaling.

21. The communication system of claim 1, wherein at least one of the equalizing output impedance and the equalizing input impedance is an electrically tunable impedance.

22. The transmitter circuit of claim 11, wherein the equalizing impedance comprises an electrically tunable inductor.

23. The receiver circuit of claim 14, wherein the equalizing impedance comprises an electrically tunable inductor.
